(19) United States
(12) Patent Application Publication
(10) Pub. No.: US 2010/0301359 A1
(43) Pub. Date: Dec. 2, 2010

(54) Light Emitting Diode Package Structure

(76) Inventor: MING-HSIUNG LIU, Sindian City (TW)

Correspondence Address: HDLS IPR Services, PO Box 220746, Chantilly, VA, 20153, US

(21) Appl. No.: 12/471,559

(22) Filed: May 26, 2009

(51) Int. Cl. H01L 33/00

(52) U.S. Cl. 257/98; 257/99; 257/E33.061; 257/E33.075

(57) ABSTRACT

An LED package structure with good heat dissipation, includes a metal plate having at least one recess, a heat-conducting insulating layer directly formed on a surface of the metal plate, a conductor layer directly formed on a surface of the heat-conducting insulating layer, at least one LED chip disposed on a bottom surface of the recess and electrically connected to the conductor layer, and at least one optical lens covering the recess. The heat-conducting insulating layer is oxides or nitrides of the metal plate.

### BACKGROUND

1. Field of the Invention

The present invention generally relates to enhance heat dissipation of a light emitting diode (LED) lamp, and more specifically, to an LED package structure having a base plate made of thermally conductive metal.

2. Description of the Related Art

Taiwan utility model patent NO. M272232 discloses an LED package structure, of which one embodiment discloses that a chip is disposed within a recess of a base plate and connected to a printed circuit formed on the base plate. The base plate is made of metal material such as aluminum, aluminum alloy, copper, or copper alloy. An insulated layer is interposed between the printed circuit and the base plate. Since the insulated layer (glue) has a relative low thermal conductivity, a large amount of heat of the printed circuit will be accumulated at the insulated layer, that is, a severe phenomenon of heat accumulation is generated.

Another embodiment discloses that the base plate is made of material such as aluminum nitride, alumina, silicon carbide, boron nitride, carbon composites, or ceramic. The printed circuit is formed by vapor deposition method, screen printing method or cofired method. In the another embodiment, since the above material has a thermal conductivity lower than that of aluminum, aluminum alloy, copper, or copper alloy, a heat-dissipating body made of metal is needed to attached to the base plate by screw locking means or thermal conductive adhesive. This means that, the base plate and the thermal conductive adhesive or gap (the screw locking means cannot completely exclude the gap between the base plate and the heat-dissipating body made of metal) is interposed between the chip with the printed circuit and the heat-dissipating body made of metal. The heat of the chip and the printed circuit cannot be quickly transferred to the heat-dissipating body made of metal to be dissipated.

Taiwan utility model patent NO. 1229948 discloses a flip-chip type LED package array and package unit thereof, which mainly discloses that an LED chip is installed on a ceramic base plate and connected to a metal connection layer on the ceramic base plate. The ceramic base plate is attached in a recess of a metal body via thermal conductive adhesive. In this case, since two layers including the ceramic base plate and the thermal conductive adhesive is interposed between the LED chip with the metal connection layer and the metal body. Thus, the heat of the LED chip with the metal connection layer cannot be quickly transferred to the metal body to be dissipated.

As mentioned above, the methods related to heat dissipation disclosed in the above patents still have room for improvement, so as to meet the high requirement of heat dissipation of high-powered LED product.

### BRIEF SUMMARY

The present invention provides an LED package structure with good heat dissipation, including a metal plate having at least one recess, a heat-conducting insulating layer directly formed on a surface of the metal plate, a conductor layer directly formed on a surface of the heat-conducting insulating layer, at least one LED chip disposed on a bottom surface of the recess and electrically connected to the conductor layer, and at least one optical lens covering the recess. The heat-conducting insulating layer is oxides or nitrides of the metal plate.

Preferably, the heat-conducting insulating layer is oxides or nitrides of the metal plate.

Preferably, the metal plate is made of made of aluminum and the heat-conducting insulating layer is alumina

Preferably, the LED package further includes fluorescent material filled between the optical lens and the recess to emit white light.

Since between the LED chip with the conductor layer and the metal plate, there is none of the insulated layer (glue), the thermal conductive adhesive and the gap existed in the prior arts, thus, the heat of the LED chip and the conductor layer can be quickly transferred to the metal plate to be dissipated. Accordingly, the long existing unsolved problem of the prior arts can be solved by the present invention.

### BRIEF DESCRIPTION OF THE DRAWINGS

The accompanying drawings are included to provide a further understanding of the invention, and are incorporated in and constitute part of this specification. The drawings illustrate embodiments of the invention and, together with the description, serve to explain the principles of the invention.

FIG. 1 is a schematic cross-section view of an LED package structure according to a preferred embodiment of the present invention.

FIG. 2 is a schematic top view of FIG. 1.

FIG. 3 is a schematic top view of an LED package structure according to another preferred embodiment of the present invention.

FIG. 4 is a schematic cross-section view of an LED package structure according to still another preferred embodiment of the present invention.

### DETAILED DESCRIPTION

Reference will now be made to the drawings to describe exemplary embodiments of the present display method, in detail. The following description is given by way of example, and not limitation.

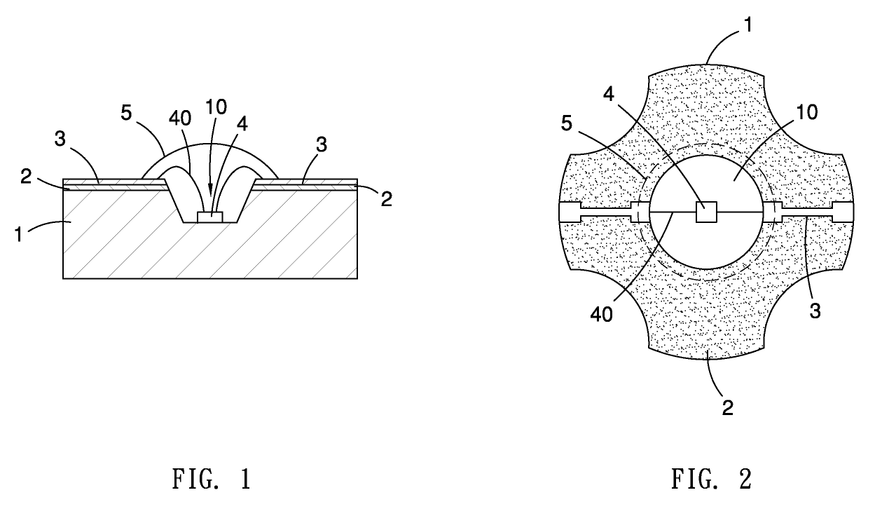

FIGS. 1-2 shows an LED package structure according to a preferred embodiment of the present invention. The LED package structure includes a metal plate 1, a heat-conducting insulating layer 2 formed on the metal plate 1, a conductor layer 3 formed on the heat-conducting insulating layer 2, an LED chip 4 and an optical lens 5.

The metal plate 1 has a surface with a cone-shaped recess 10. The recess 10 may be fabricated by laser drilling, mechanical drilling, etching and so on. The gradient of the sidewalls around the recess 10 is about 45 degrees, so as to get a good effect of light reflection. The material of metal plate 1 is preferably selected from metals which has good thermal conductivity and is easy to be formed into the subsequent structure, such as aluminum.

The heat-conducting insulating layer 2 is a layer which is directly formed on the surface of the metal plate 1, such as metallic compound layer (that is, oxide film layer or nitride film layer) which has good insulativity and thermal conductivity. In case of that the metal plate is made of aluminum, the heat-conducting insulating layer 2 is alumina or aluminum nitride, and this point dose not disclosed in the prior arts. The heat-conducting insulating layer 2 also can be a layer of ceramic materials or polymeric materials. The methods of forming the heat-conducting insulating layer 2 include thermal oxidation, vapor deposition, anodic treatment and so on. In addition, the heat-conducting insulating layer 2 is only formed the surface of the metal plate 1 which has the recess 10 formed therein and the heat-conducting insulating layer 2 is not formed on a surface of the recess 10.

The conductor layer 3 is a layer which is directly formed on the heat-conducting insulating layer 2. For example, after the step of roughening the surface of the heat-conducting insulating layer 2, a layer of copper is plated on heat-conducting insulating layer 2 by the chemical copper electroplating method, then an etch patterning step is performed to get the conductor layer 3 having a predesigned circuit pattern. The circuit pattern includes pads used for linking to the N electrode and the P electrode of LED chip 4.

The LED chip 4 may be attached to a bottom surface of the recess 10 via thermal conductive adhesive or soldering, and the bottom surface of the recess 10 is a part of the metal plate 1. The N electrode and the P electrode of LED chip 4 are linked to the pads of the metal conductor layer 3 via wire 40. The LED chip 4 can be chosen from red LED chip, green LED chip or blue LED chip. If the LED chip 4 is designed to emit white light, the LED chip 4 can use a high powered blue LED chip using with YAG fluorescent material, or other fluorescent materials which can use with the blue LED chip to emit white light.

The optical lens 5 is used to cover the recess 10 and has appropriate optical design to improve light output efficiency of the LED chip 4. The optical lens 5 can be made of plastic or glass. The optical lens 5 can be secured by means of clipping or bonding. The above mentioned fluorescent material can be filled between the optical lens 5 and the recess 10.

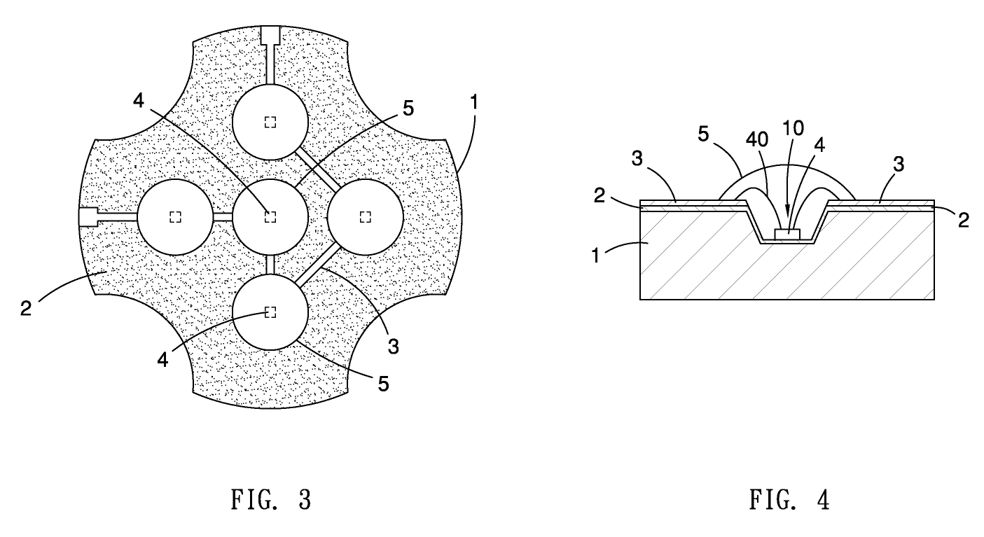

FIG. 3 shows an embodiment in which there is a plurality of LED chips 4 disposed on the metal plate 1. In this embodiment, a plurality of recesses 10 should be formed in the metal plate 1 according to the number of the LED chips 4. The conductor layer 3 formed on the heat-conducting insulating layer 2 which is formed on the metal plate 1, is used to connect these LED chips 4, for example in parallel or series. The LED chip 4 in each of the recess 10 can be a blue LED chip using with the above fluorescent material filled in each of the recess 10, so as to emit a plurality of beams of white light.

If need, the circuit pattern of the conductor layer 3 can also include structures which are used to weld SMT elements of a control circuit, for example, resistance, capacitance, power crystal, integrated circuit (IC) and so on. The control circuit is used to control work of the LED chips 4. FIG. 4 shows another preferred embodiment of the present invention, in which the heat-conducting insulating layer 2 extends into the above mentioned recess 10. Furthermore, the above mentioned pads of the conductor layer 3 also extend into the recess 10, to facilitate the assembling process of the P electrode and N electrode of the LED chip 4 and the corresponding pad, for example using flip-chip assembly methods.

Compared with the conventional technology, since the LED chip 4 of one embodiment of the present invention is directly secured on the metal plate 1, that is there is no heat-conducting insulating layer interposed between the LED chip and the metal plate, so that the heat produced by the LED chip 4 can be quickly transferred to the metal plate 1 to be dissipated. In another embodiment of the present invention, although there is a heat-conducting insulating layer 2 interposed between the LED chip 4 and the metal plate 1, the heat-conducting insulating layer 2 has a good thermal conductivity which is at least better than that of the thermal conductive adhesive or gap of the conventional technology. Therefore, the heat of the LED chip 4, relatively speaking, can be quickly transferred to the metal plate 1 to be dissipated. As the heat of the conductor layer 3 of the present invention is transferred to the metal plate 1 via the heat-conducting insulating layer 2, however, since the heat-conducting insulating layer 2 has a good thermal conductivity which is at least better than that of the insulated layer (glue) of the conventional technology. Therefore, not only does not occur the severe phenomenon of heat accumulation, but also the heat can be quickly transferred to the metal plate 1 to be dissipated. Hence, in present invention, the problem of heat dissipation of the LED chip 4 and the conductor layer 3 has been properly deal with. Therefore, the overall cooling effect of the embodiment of the present invention is significantly better than that of the conventional technology.

Furthermore, a metal heat sink such as copper or aluminum fins, can be attached to another surface of the metal plate 1 (the surface of the metal plate does not have the recess 10), so as to improve the heat dissipation effect thereof.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. An light emitting diode (LED) package structure, comprising:
a metal plate having a surface with at least one recess;
a heat-conducting insulating layer directly formed on a surface of the metal plate;
a conductor layer directly formed on a surface of the heat-conducting insulating layer;
at least one LED chip disposed on a bottom surface of the recess and electrically connected to the conductor layer; and
at least one optical lens covering the recess; wherein the heat-conducting insulating layer is oxides or nitrides of the metal plate.

2. The LED package structure as claimed in claim 1, wherein the metal plate is made of made of aluminum and the heat-conducting insulating layer is alumina.

3. The LED package structure as claimed in claim 2, further comprising fluorescent material filled between the optical lens and the recess.

4. An LED package structure, comprising:
a metal plate having a surface with at least one recess;
a heat-conducting insulating layer directly formed on a surface of the metal plate;
a conductor layer directly formed on a surface of the heat-conducting insulating layer;
at least one LED chip disposed on a bottom surface of the recess and electrically connected to the conductor layer; and
at least one optical lens covering the recess;
wherein the metal plate is made of made of aluminum and the heat-conducting insulating layer is made of ceramic materials including alumina.

5. The LED package structure as claimed in claim 4, further comprising fluorescent material filled between the optical lens and the recess.
